(19) United States
(12) Patent Application Publication
(10) Pub. No.: US 2005/0282364 A1
(43) Pub. Date: Dec. 22, 2005

(54) Method of fabricating a semiconductor thin film and semiconductor thin film fabrication apparatus

(75) Inventors: Masanori Seki, Tenri-shi (JP); Tetsuya Inui, Nara-shi (JP); Yoshihiro Taniguchi, Nara-shi (JP)

Correspondence Address: EDWARDS & ANGELL, LLP, P.O. BOX 55874, BOSTON, MA, 02205, US

(73) Assignee: Sharp Kabushiki Kaisha

(21) Appl. No.: 11/155,072

(22) Filed: Jun. 16, 2005

(30) Foreign Application Priority Data
Jun. 17, 2004 (JP) 2004-179720

(51) Int. Cl. H01L 21/00; C30B 11/00; H01L 21/20; H01L 21/84; H01L 21/36

(52) U.S. Cl. 438/479; 438/149; 117/200

(57) ABSTRACT

A fabrication method of a semiconductor thin film including a polycrystalline semiconductor region by irradiating a precursor semiconductor thin film substrate with at least two types of laser beams, and melting-recrystallizing the precursor semiconductor thin film, wherein the radiation timing or power density of the at least two types of laser beams is controlled according to change in reflectance of a site of the precursor semiconductor thin film substrate irradiated with a predetermined reference laser beam.

This nonprovisional application is based on Japanese Patent Application No. 2004-179720 filed with the Japan Patent Office on Jun. 17, 2004, the entire contents of which are hereby incorporated by reference.

### BACKGROUND OF THE INVENTION

1. Field of the Invention

The present invention relates to a method of fabricating a semiconductor thin film utilizing an energy beam, particularly a laser beam, and a fabrication apparatus therefor.

2. Description of the Background Art

A polycrystalline thin film transistor corresponds to a transistor formed at a polycrystalline semiconductor thin film obtained by recrystallization of an amorphous semiconductor thin film. Such a polycrystalline thin film transistor is expected to allow high speed operation by virtue of the great charge carrier mobility, as compared to an amorphous thin film transistor corresponding to a transistor directly formed at an amorphous semiconductor thin film. The polycrystalline thin film transistor has the possibility of realizing large-scale integrated circuits on glass substrates as well as driving systems of liquid crystal devices.

The usage of a thin film transistor of crystalline silicon allows formation of a switching element for the pixel region in a liquid crystal display, for example, as well as a driving circuit for the pixel peripheral region and some peripheral circuits. Such elements and circuits can be formed on one substrate. Since it is therefore no longer necessary to mount an additional driver IC or driving circuit substrate in the display device, display devices can be produced at lower cost.

Another advantage of using a thin film transistor of crystalline silicon is the capability of reducing the dimension of the transistor. The switching elements constituting the pixel region become smaller to allow a higher aperture ratio for the display device. Thus, a display device of high luminance and high accuracy can be provided.

A polycrystalline semiconductor thin film is obtained by subjecting an amorphous semiconductor thin film produced through vapor deposition to thermal annealing for a long period of time below the strain point of glass (approximately 600-650° C.), or to optical annealing to receive light such as by a laser having a high energy density. Optical annealing is considered to be extremely effective for crystallization of a semiconductor thin film of high mobility since high energy can be applied to only the semiconductor thin film without raising the temperature of the glass substrate up to the strain point.

The aforementioned recrystallization technique employing an excimer laser is generally referred to as ELA (Excimer Laser Annealing), employed in industrial application as a laser crystallization technique superior in productivity. In accordance with the ELA, a glass substrate having an amorphous silicon thin film formed is heated to approximately 400° C. A linear excimer laser beam of approximately 200-400 mm in length and 0.2-1.0 mm in width is applied in pulsed radiation towards the amorphous silicon thin film on the glass substrate that is moved at a predetermined rate. By this method, a polycrystalline silicon thin film having an average grain size substantially equal to the thickness of the amorphous silicon thin film is obtained. The portion of amorphous silicon thin film irradiated with the excimer laser is melted, not thoroughly, but partially, in the direction of the thickness so as to leave an amorphous region. Therefore, a crystal nucleus is generated everywhere all over the laser-irradiated region plane, whereby silicon crystals will grow towards the top layer of the silicon thin film.

In order to obtain a display device of further higher performance, the crystal grain size of polycrystalline silicon must be increased and/or the orientation of the silicon crystal controlled. Various approaches have been proposed in order to obtain a polycrystalline silicon thin film having performance similar to that of monocrystal silicon. Among such various approaches, the technique of growing a crystal laterally (referred to as “super lateral growth” hereinafter) is known (refer to International Publication No. WO97/45827). Specifically, a silicon thin film is irradiated with a pulsed laser of an extremely small width such as several μm to be melted and agglomerated for crystallization throughout the entire region in the direction of thickness of the laser-irradiated region. Since the boundary between the molten portion and non-molten portion is perpendicular to the glass substrate plane, the crystals from the crystal nucleus generated thereat all grow laterally. As a result, needle-like crystals of uniform size, parallel to the glass substrate plane, are obtained by one pulse of laser radiation. Although the length of crystal formed by one pulse of laser radiation is approximately 1 μm, sequential emission of laser pulses so as to overlap with a portion of the previous needle-like crystal formed by laser radiation of the preceding pass allows succession of the already-grown crystal to result in a crystal grain of a longer needle shape.

In accordance with the super lateral growing method set forth above, the length of crystal grown through one pulse of laser radiation is approximately 1 μm (FIG. 8A). When a region having at least two times the length of crystal is melted, submicron crystals will be generated at the center portion of the molten region (FIG. 8B). Such submicron crystals are grown, not laterally, but vertically with respect to the substrate under the dominance of heat conduction towards the substrate. A needle-like crystal having a significantly increased length of crystal cannot be obtained by increasing the molten region. Therefore, pulse laser radiation must be repeated at a pitch as extremely small as approximately 0.4-0.7 μm in accordance with the super lateral growth. Achieving crystallization over the entire substrate employed in a display device and the like was therefore extremely time-consuming. There was a problem that the fabrication efficiency is extremely poor.

In view of forming a longer needle-shaped crystal through one pulse of laser radiation, various methods are proposed such as heating the substrate with a heater, heating the substrate or underlying film through a laser, or the like (for example, refer to Japanese Patent Laying-Open No. 06-291034). However, the method based on heating the substrate with a heater is disadvantageous in that the temperature must be maintained for a long period of time over a large range, leading to the possibility of inducing modification of the substrate, underlying film, and semiconductor film. The cooling time will differ if the temperature is not constant, resulting in variation in the size of the grains to cause variation in the property of the semiconductor. This becomes more significant as the average size of the crystal grain increases. In the case where heating is conducted through laser, it is difficult to maintain the temperature at a constant level since variation in the radiation energy of the laser output apparatus will directly lead to variation in temperature.

For the purpose of maintaining the surface of the semiconductor thin film at a constant temperature, there is proposed the technique of controlling the laser oscillator by sensing change in temperature at the semiconductor substrate surface. (For example, refer to Japanese Patent Laying-Open No. 04-338631). The approach disclosed in the publication of Japanese Patent Laying-Open No. 04-338631 is directed to sensing the temperature of the laser-irradiated portion using a radiation thermometer to modulate the laser beam according to the sensed result. It is to be noted that even the fastest response rate of a radiation thermometer is on the order of several milliseconds. Therefore, there was a problem that it cannot be applied to measuring the temperature of a laser processing location using a laser beam that has a pulse width on the order of several hundred nanoseconds to microsecond.

### SUMMARY OF THE INVENTION

In view of the foregoing, an object of the present invention is to provide an apparatus and method of fabricating a semiconductor thin film employing a laser beam having a pulse width on the order of several hundred nanoseconds to microsecond, including means for sensing change in the temperature of a laser-irradiated portion on the order set forth above.

Another object of the present invention is to provide an apparatus and method of fabricating a semiconductor thin film including means for heating a semiconductor substrate up to a specified temperature for a period of time on the order of several hundred nanoseconds to microsecond.

A further object of the present invention is to provide a method and apparatus of fabricating a semiconductor thin film for forming longer needle-like crystals with little variation in super lateral growth.

According to an aspect of the present invention, a fabrication method of a semiconductor thin film having a polycrystalline semiconductor region includes the steps of irradiating a precursor semiconductor thin film substrate with at least two types of laser beams, and melting-recrystallizing the precursor semiconductor thin film, wherein the radiation timing or power density of the at least two types of laser beams is controlled according to change in reflectance of a site of the precursor semiconductor thin film substrate irradiated with a predetermined reference laser beam.

Preferably, the at least two types of laser beams include a first laser beam having a wavelength that can be absorbed by the precursor semiconductor thin film and energy that can melt the precursor semiconductor thin film, and a second laser beam having a wavelength and energy that can control the process of recrystallization of the molten precursor semiconductor thin film.

Preferably, the reference laser beam is the second laser beam. The radiation timing or power density of the first or second laser beam is controlled according to change in reflectance of the second laser beam to melting-recrystallize the precursor semiconductor thin film.

Preferably, the first laser beam is emitted according to change in reflectance obtained from the power density after reflection of the second laser beam emitted at the precursor semiconductor thin film substrate with respect to the power density before reflection of the second laser beam.

Preferably, the first laser beam is emitted after the reflectance reaches a predetermined value.

Preferably, the predetermined value of reflectance is determined depending upon the desired length of crystal and the power density of the first laser beam.

Preferably, the power density of the first laser beam is controlled according to change in reflectance obtained from the power density after reflection of the second laser beam emitted at the precursor semiconductor thin film substrate with respect to the power density before reflection of the second laser beam.

Preferably, the power density of the first laser beam is determined from the relationship between the reflectance immediately before emission of the first laser beam and the desired length of crystal.

Preferably, the power density of the second laser beam is controlled according to change in reflectance obtained from the power density after reflection of the second laser beam emitted at the precursor semiconductor thin film substrate with respect to the power density before reflection of the second laser beam.

Preferably, the power density of the second laser beam is determined from the relationship between the desired length of crystal and the reflectance immediately before emission of the first laser beam.

Preferably, the first laser beam has a wavelength in the ultraviolet range or visible range. The second laser beam has a wavelength in the visible range or infrared range.

Preferably, the second laser beam has a wavelength in the range of 9-11 μm.

Preferably, the crystal grown during recrystallization is grown substantially parallel to the plane of the semiconductor thin film substrate.

According to another aspect of the present invention, a semiconductor thin film fabrication apparatus includes at least two light sources that can irradiate a precursor semiconductor thin film substrate with at least two types of laser beams, a sensing unit that can sense change in reflectance of a site of the precursor semiconductor thin film substrate irradiated with a predetermined reference laser beam, and a control unit that can control the radiation timing or power density of the at least two types of laser beams according to change in reflectance of a site of the precursor semiconductor thin film substrate irradiated with the reference laser beam.

Preferably, the at least two laser light sources include a first laser light source emitting a first laser beam having a wavelength that can be absorbed by the precursor semiconductor thin film and energy that can melt the precursor semiconductor thin film, and a second laser light source emitting a second laser beam having a wavelength and energy that can control the process of recrystallization of the molten precursor semiconductor thin film. The sensing unit senses change in reflectance of a site irradiated with the second laser beam, when the reference laser beam is the second laser beam. The control unit controls the radiation timing or power density of the first laser beam or second laser beam according to change in reflectance of a site of the precursor semiconductor thin film substrate irradiated with the second laser beam.

Preferably, the sensing unit can sense change in reflectance obtained from the power density after reflection of the second laser beam emitted at the precursor semiconductor thin film substrate with respect to the power density before reflection of the second laser beam.

Preferably, the sensing unit is formed of an optical sensor and a signal processing circuit that can process a signal from the optical sensor. The optical sensor is arranged so as to sense the second laser beam before reflection at the precursor semiconductor thin film substrate and the second laser beam after reflection at the precursor semiconductor thin film substrate. The signal processing circuit processes a signal indicating the power density of the second laser beam before reflection, and a signal indicating the power density of the second laser beam after reflection, transmitted from the optical sensor, to generate a signal indicating reflectance.

Preferably, the first laser light source emits a first laser beam having a wavelength in the ultraviolet range. The second light source emits a second laser beam having a wavelength in the visible range or infrared range.

Preferably, the second laser beam emitted from the second laser light source has a wavelength of 9-11 μm.

Preferably, the crystal grown during recrystallization is grown substantially parallel to the plane of the semiconductor thin film substrate.

Since the length of crystal formed by each radiation is set uniformly in accordance with the present invention, a method of fabricating in stability a semiconductor thin film including a polycrystalline semiconductor region having the length of crystal increased significantly in the lateral growing distance, and a fabrication apparatus therefor can be provided. By the fabrication method and fabrication apparatus of the present invention, a thin film transistor having the performance greatly improved, as compared to a conventional one, can be fabricated in stability. Further, since the feeding pitch in super lateral growth can be increased significantly in accordance with the fabrication method of the present invention, the crystallization processing time can also be reduced significantly.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a graph representing the relationship between the time and power density of first and second laser beams.

FIG. 2 is a graph representing the relationship between the energy fluence of the first laser beam and the length of crystal.

FIG. 3 is a graph representing the radiation waveform of the second laser beam before and after reflection at the precursor semiconductor thin film substrate.

FIG. 4 is a graph representing the relationship between the radiation time and power density of the second laser beam.

FIG. 5 is a graph representing the relationship between the time and power density of first and second laser beams.

FIG. 6 is a schematic sectional view of a substrate composite.

FIG. 7 is a schematic diagram of an example of a semiconductor device of the present invention.

FIGS. 8A and 8B are schematic diagrams of crystals grown by super lateral growth.

FIG. 9 is a diagram representing an operation of a signal processing circuit of the present invention.

FIGS. 10, 11 and 12 are diagrams to describe an operation of a control unit 23 according to first, second, and third methods, respectively, of the present invention.

### DESCRIPTION OF THE PREFERRED EMBODIMENTS

Fabrication Method of Semiconductor Thin Film

The semiconductor thin film fabrication method of the present invention is based on a method of fabricating a semiconductor thin film including a polycrystalline semiconductor region by irradiating a precursor semiconductor thin film substrate with at least two types of laser beams, and melting-recrystallizing the precursor semiconductor thin film. The radiation timing or power density of the at least two types of laser beams is controlled according to change in reflectance of a site of the precursor semiconductor thin film substrate irradiated with a predetermined reference laser beam.

The type of the laser beam employed in the present invention is not particularly limited, and may be any type as long as a precursor semiconductor thin film is melting-recrystalized through irradiation of a precursor semiconductor thin film substrate with at least one of the two types of laser beams employed to result in formation of a polycrystalline semiconductor region. In particular, the laser beams of the present invention preferably include a first laser beam having a wavelength that can be absorbed by a precursor semiconductor thin film, and energy that can melt the precursor semiconductor thin film, and a second laser beam having a wavelength and energy that can control the process of recrystallization of the molten precursor semiconductor thin film.

The semiconductor thin film fabrication method of the present invention has technical significance in that radiation or power density of a laser beam is controlled according to change in reflectance of a site irradiated with a predetermined reference laser beam. As used herein, “reference laser beam” is one laser beam determined arbitrarily in advance from the at least two types of laser beams. The reference laser beam is emitted to a precursor semiconductor thin film prior to emission of a laser beam directed to melting-recrystallization of the precursor semiconductor thin film. In the case where the first and second laser beams set forth above are employed, the second laser beam may be used as the reference laser beam. Alternatively, another laser beam, (third laser beam) may be applied as the reference laser beam.

In the present invention, the laser beam directed to melting-recrystallization of a precursor semiconductor thin film is controlled according to change in reflectance of a site irradiated with the reference laser beam. As used herein, “change in reflectance” refers to change in the ratio of the power density after reflection of the reference laser beam emitted at the precursor semiconductor thin film with respect to the power density before reflection of the reference laser beam.

In the present invention, the radiation timing or power density of a laser beam directed to melting-recrystallization is controlled according to change in reflectance at a site of the precursor semiconductor thin film irradiated with the reference laser beam. In the case where “at least two types of laser beams” include the first and second laser beams set forth above, the subject of control according to change in reflectance of the reference laser beam may be either the first laser beam or the second laser beam.

In accordance with the semiconductor thin film fabrication method of the present invention, a method of fabricating in stability a semiconductor thin film including a polycrystalline semiconductor region having the length of crystal increased significantly in the lateral growing distance, absent of difference in the length of crystal formed due to variation in energy for each radiation, and a fabrication apparatus therefor can be provided. By virtue of such a fabrication method of the present invention, a thin film transistor having the performance improved significantly, as compared to a conventional one, can be fabricated in stability. Further, the processing time required for crystallization can be reduced significantly since the feeding pitch in super lateral growth can be increased significantly.

It is now assumed that the power density is P(t), the radiation period of time is t1, and the area of irradiation is S. The laser beam energy can be expressed as P×t1×S corresponding to a rectangular waveform, where P(t)=P, and (∫₀^{t1}P(t)dt)×S) corresponding to a waveform other than a rectangle.

In the semiconductor thin film fabrication method of the present invention, the at least two types of laser beams preferably include a first laser beam having a wavelength that can be absorbed by the precursor semiconductor thin film and energy that can melt the precursor semiconductor thin film, and a second laser beam having a wavelength and energy that can control the process of recrystallization of the molten precursor semiconductor thin film, wherein the precursor semiconductor thin film is melting-recrystallized while controlling the radiation timing or power density of the first or second laser beam according to change in reflectance of the second laser beam employed as the reference laser beam. There is an advantage of simplifying the structure of the apparatus by using the second laser beam as the reference laser beam instead of using a third laser beam as the reference laser beam.

In view of the fabrication method of a semiconductor thin film of the present invention set forth above, any one of the following approaches of (1)-(3) is particularly preferable.

(1) Emitting the first laser beam according to change in reflectance of the second laser beam identified as the reference laser beam (referred to as “first method” hereinafter);

(2) Controlling the power density of the first laser beam according to change in reflectance of the second laser beam identified as the reference laser beam (referred to as “second method” hereinafter); and

(3) Controlling the power density of the second laser beam according to change in reflectance of the second laser beam identified as the reference laser beam (referred to as “third method” hereinafter).

Each of these methods will be described in detail hereinafter.

(1) First Method

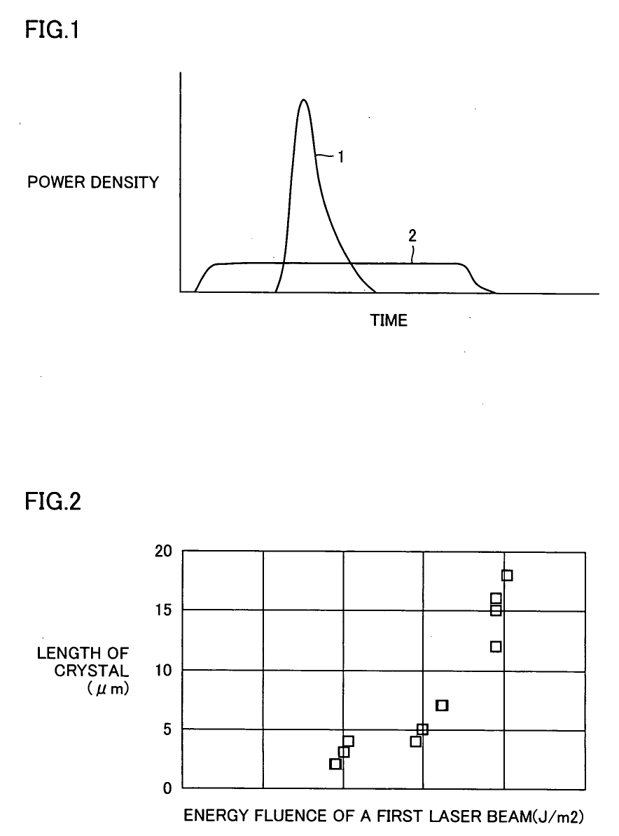

FIG. 1 is a graph to describe the first method of fabricating a semiconductor thin film of the present invention. In this graph representing the relationship between the period of time and power density of the first and second laser beams, the power density is plotted along the ordinate and the period of time is plotted along the abscissa. In FIG. 1, designation 1 represents the radiation waveform of the first laser beam emitted, whereas designation 2 represents the radiation waveform of the second laser beam emitted.

FIG. 2 is a graph representing results of experiments carried out when a second laser beam is emitted, and then a first laser beam is emitted without sensing change in reflectance of the second laser beam. In this graph representing the relationship between the energy fluence of the first laser beam and the length of crystal, the energy fluence (J/m²) of the first laser beam is plotted along the abscissa, whereas the length of crystal (μm) is plotted along the ordinate.

It is appreciated from FIG. 2 that the length of crystal varies for each radiation despite of the energy fluence of the first laser beam being substantially the same. This difference is due to the fact that the energy of the second laser beam varies for each radiation. Such variation in the length of crystal will adversely affect the property of the obtained semiconductor.

In accordance with the first method of the present invention, the second laser beam is emitted as the reference laser beam, as shown in FIG. 1 onto a precursor semiconductor thin film substrate having an amorphous semiconductor region. Then, the reflectance obtained from the power density after reflection of the second laser beam at the precursor semiconductor thin film substrate with respect to the power density before reflection of the second laser beam is sensed, followed by emission of the first laser beam when the aforementioned reflectance attains a predetermined value. By virtue of the first method, variation in the length of crystal between each radiation can be reduced to obtain a needle like crystal having the length of crystal increased significantly.

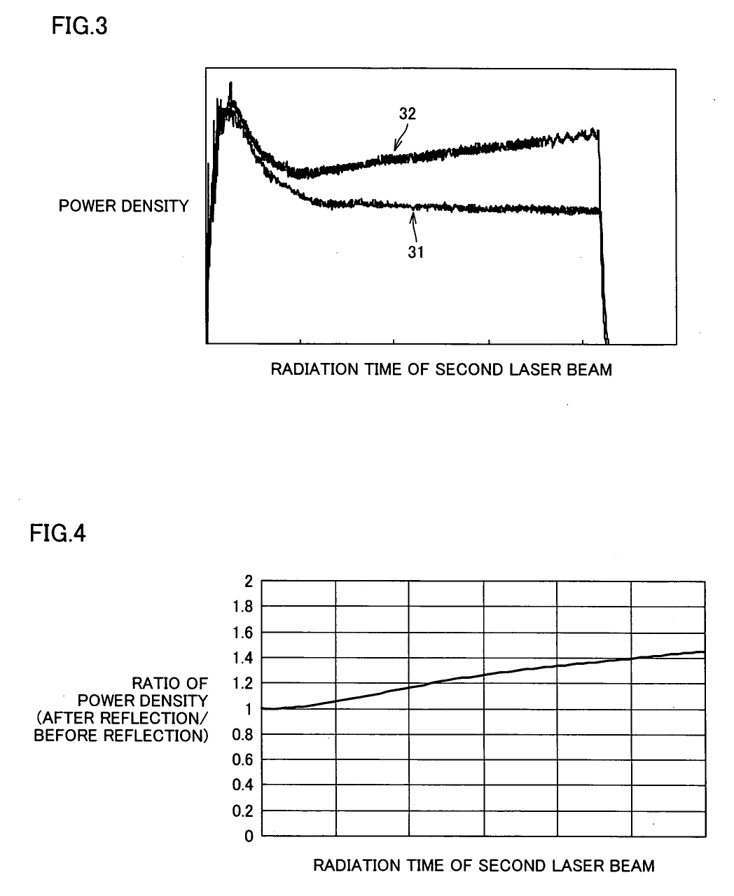

The radiation waveform of the second laser beam before reflection and after reflection from the precursor semiconductor thin film substrate is shown in FIG. 3. Designation 31 represents the radiation waveform before reflection. Designation 32 represents the radiation waveform after reflection. The power density is plotted along the ordinate, whereas the radiation time is plotted along the abscissa. It is appreciated from FIG. 3 that the power density over time of radiation differs between the laser beam before reflection and the laser beam after reflection.

The change in reflectance obtained by the power density succeeding reflection with respect to the power density preceding reflection in accordance with the elapse of the radiation time calculated from the results of FIG. 3 is shown in FIG. 4. In the graph of FIG. 4, the ratio of the power density of the second laser beam succeeding reflection to the power density of the second laser beam preceding reflection is plotted along the ordinate, whereas the radiation period of time is plotted along the abscissa. It is appreciated from FIG. 4 that the reflectance obtained from the power density of the second laser beam succeeding reflection to the power density of the second laser beam preceding reflection changes in accordance with increase of the radiation time. Since a longer radiation time exhibits increase in temperature at the precursor semiconductor thin film substrate, it is considered that the reflectance obtained from the power density after reflection of the second laser beam with respect to the power density of the second laser beam before reflection changes in accordance with elevation in temperature.

When a second laser beam having a wavelength and energy that can control the process of recrystallization of a molten precursor semiconductor thin film is emitted onto a precursor semiconductor thin film substrate having an amorphous semiconductor region, the precursor semiconductor thin film or semiconductor thin film substrate is heated. Since the energy of the second laser beam varies at each radiation, the temperature of the precursor semiconductor thin film and precursor semiconductor thin film substrate at the time of emission of the first laser beam will differ for each emission of the second laser beam even if the elapsed time from the emission of the second laser beam to emission of the first laser beam is identical. Accordingly, the length of crystal differed at each radiation of the second laser beam, as shown in FIG. 2, even if the fluence energy of the first laser beam is identical under laser processing conditions directed to increasing the length of lateral crystal significantly.

The first method of the present invention is directed to sensing change in the temperature of the precursor semiconductor thin film or semiconductor thin film substrate caused by irradiation with the second laser beam through change in the reflectance obtained from the power density after reflection of the second laser beam at the precursor semiconductor thin film with respect to the power density before reflection of the second laser beam, and then emitting the first laser beam when the precursor semiconductor thin film or semiconductor thin film substrate reaches a predetermined temperature. Accordingly, the crystal is less susceptible to variation in the energy at each emission of the second laser beam, allowing a stable length of crystal for each radiation.

The temperature change of the precursor semiconductor thin film caused by irradiation with the second laser beam identified as the reference laser beam can be sensed through the change in reflectance of the second laser beam at the precursor semiconductor thin film substrate. Semiconductor materials and metal materials generally have a predetermined reflectance with respect to light of each wavelength. This is because the reflectance depends on the refractive index at each wavelength of each material. Further, the refractive index has dependency on the temperature of the material. Therefore, the reflectance exhibits temperature dependency.

The inventors obtained the results set forth below from experiments. Specifically, the reflectance of a laser beam having a wavelength of 10.6 μm from a precursor semiconductor thin film substrate including an amorphous semiconductor region is approximately 16%, approximately 19%, and approximately 20% at room temperature (25° C.), approximately 300° C., and approximately 600° C., respectively. The reflectance was obtained as set forth below. A laser beam having a wavelength of approximately 10.6 μm corresponding to a level that induces almost no elevation in temperature at a precursor semiconductor thin film substrate including an amorphous semiconductor region was applied towards the substrate obliquely. The pulse energy before and after reflection from the substrate was measured by an energy meter. The reflectance was obtained by the ratio of the measured value after reflection with respect to the measured value before reflection. The film structure of the semiconductor thin film substrate employed in the measurement was formed of a glass substrate, a 1000 Å silicon oxide film (SiO₂) and a 450 Å amorphous silicon film (a-Si).

The reflectance corresponding to temperatures other than the room temperature was obtained based on measurements while heating the substrate with a heater. The power density of the second laser beam at a semiconductor thin film substrate at respective temperatures can be obtained by (power density of second laser beam before reflection)×(reflectance at each temperature). Assuming that the second laser beam has an energy fluence of 8100 J/m² and a pulse width (radiation time) of 130 μsec, the sensed power density of reflected light of the second laser beam is 10.0 MW/m², 11.9 MW/m², and 12.5 MW/m² at room temperature, 300° C., and 600° C., respectively. It is therefore appreciated that, in the case where the first laser beam is to be emitted when the temperature of the precursor semiconductor thin film is 300° C., the first laser beam should be emitted upon sensing change in the power density of the second laser beam from 10.0 MW/m² to 11.9 MW/m². When the temperature of the precursor semiconductor thin film is in the vicinity of 300° C., the power density of reflected light varies 0.03 MW/m² for every 10° C. change in temperature of the precursor semiconductor thin film. It is desirable to control the timing of emitting the first laser beam upon identifying this change of 0.03 MW/m².

In the first method, the energy fluence of the first laser beam and the second laser beam takes constant values. In this case, the energy fluence of the first laser beam is selected from the range of preferably 1500 to 3500 J/m², further preferably 2500 to 3000 J/m². This is because an energy fluence less than 1500 J/m² for the first laser beam tends to disable formation of a crystal grain having a long crystal length, and an energy fluence exceeding 3500 J/m² for the first laser beam tends to cause ablation of the Si thin film.

When the pulse width of the second laser beam is 130 μsec, the energy fluence of the second laser beam is selected preferably from the range of 7500 to 10000 J/m², more preferably from the range of 8000 to 9000 J/m². This is because an energy fluence less than 7500 J/m² for the second laser beam tends to disable formation of a crystal grain having a long crystal length, and an energy fluence exceeding 10,000 J/m² for the second laser beam tends to cause ablation of the Si thin film, as well as deformation and/or damage of the semiconductor thin film substrate by the second laser beam.

(2) Second Method

In accordance with the second method of the present invention, the precursor semiconductor thin film is irradiated with the second laser beam identified as the reference laser beam as shown in FIG. 1, and then irradiated with the first laser beam at an elapse of a predetermined time. The second method differs from the first method set forth above in that the ratio of the power density of the second laser beam after reflection from the precursor semiconductor thin film substrate with respect to the power density of the second laser beam before reflection is sensed, and the power density of the first laser beam is controlled according to the sensed result immediately before emission of the first laser beam.

Specifically, the power density of the first laser beam is increased when the ratio of the power density of the second laser beam sensed is smaller than a predetermined value. In contrast, when the power density of the reflected light is larger than the predetermined value, the power density of the first laser beam is reduced. It is appreciated from FIG. 2 that the length of crystal increases in accordance with a higher energy fluence of the first laser beam. By controlling the energy fluence of the first laser beam, the length of crystal can be controlled.

In accordance with the second method, a semiconductor thin film having a desired length of crystal can be fabricated by controlling the power density of the first laser beam through modification of the set value of the radiation energy of the first laser beam according to variation in the power density of reflected light of the second laser beam.

In the second method, the point in time of initiating radiation of the first laser beam is fixed. The radiation initiation time of the first laser beam is determined depending upon the desired length of crystal, the power density of the first laser beam, the power density of the second laser beam, and the pulse width of the second laser beam. If radiation is initiated before elapse of a predetermined period of time, the length of crystal tends to become shorter than the desired length. If radiation is initiated after elapse of time corresponding to the pulse width of the second laser beam, the length of crystal also tends to become shorter than the desired length.

For example, when the desired length of crystal is at least 10 μm, the energy fluence of the first laser beam is 3000 J/m², the energy fluence of the second laser beam is 8100 J/m², and the pulse width (radiation time) is 130 μsec, the radiation initiation time of the first laser beam is preferably in the range of 110-130 μsec, more preferably in the range of 120-130 μsec, from the radiation initiation time of the second laser beam. This is because, if radiation of the first laser beam is initiated at a point in time before 110 μsec from the initiation of the second laser beam radiation, the length of crystal is liable to become shorter than the desired length. Furthermore, if radiation of the first laser beam is initiated at a point in time after 130 μsec from the initiation of the second laser beam radiation, the length of crystal is liable to become shorter than the desired length.

(3) Third Method

FIG. 5 is a graph to describe the third method of fabricating a semiconductor thin film of the present invention, indicating the relationship between the time and power density of first and second laser beams. In FIG. 5, the power density is plotted along the ordinate, whereas time is plotted along the abscissa. Designation 3 indicates the radiation waveform of the first laser beam. Designation 4 indicates the radiation waveform of the second laser beam.

In the third method of the present invention, the precursor semiconductor thin film is irradiated with the second laser beam identified as the reference laser beam, and then irradiated with the first laser beam at an elapse of a predetermined time. The third method differs from the second method set forth above in that the ratio of the power density of the second laser beam on the precursor semiconductor thin film is sensed, and the power density of the second laser beam is controlled according to the sensed result immediately before emission of the second laser beam.

Specifically, the power density of the second laser beam is increased when the ratio of the power density of the second laser beam sensed is smaller than a predetermined value. In contrast, when the power density of reflected light is larger than the predetermined value, the power density of the second laser beam is reduced.

Microstructure crystals as shown in FIG. 8B are formed at the center area of the laser-irradiated portion since lateral growth is suppressed by the heat conduction in the direction of the substrate. Therefore, in order to suppress generation of microstructure crystals formed at the center area of the laser radiation region and further increase the distance of lateral growth, agglomeration at the center area of the laser-irradiated portion is to be retarded. In accordance with the third method, the process of recrystallization of molten silicon can be controlled (adjustment of cooling rate) by controlling the power density of the second laser beam towards molten silicon. A stable length of crystal can be achieved at each radiation.

Likewise the second method set forth above, the point in time of initiating radiation of the first laser beam is fixed in the third method. The point in time of initiating radiation of the first laser beam is determined depending upon the desired length of crystal, the power density of the first laser beam, the power density of the second laser beam, and the pulse width of the second laser beam. If radiation is initiated before elapse of the predetermined period of time, the length of crystal tends to become shorter than the desired length. If radiation is initiated after elapse of time corresponding to the pulse width of the second laser beam, the length of crystal also tends to become shorter than the desired length.

For example, when the desired length of crystal is at least 10 μm, the energy fluence of the first laser beam is 3000 J/m², the energy fluence of the second laser beam is 8100 J/m², and the pulse width (radiation time) is 130 μsec, the radiation initiation time of the first laser beam is preferably at a point of time in the range of 110-130 μsec, and more preferably in the range of 120-130 μsec, from the initiation of the second laser beam radiation. This is because, if radiation of the first laser beam is initiated at a point in time before 110 μsec from the initiation of the second laser beam radiation, the length of crystal is liable to become shorter than the desired length. Furthermore, if radiation of the first laser beam is initiated at a point in time after 130 μsec from the initiation of the second laser beam radiation, the length of crystal is liable to become shorter than the desired length.

In the case where at least two types of laser beams include the first laser beam and the second laser beam set forth above in the fabrication method of a semiconductor thin film of the present invention, it is preferable to use a first laser beam having a wavelength in the ultraviolet range since great energy can be applied to the thin film in an extremely short period of time on the order of ns to μs, and light of the ultraviolet range can be absorbed favorably by a silicon thin film. As used herein, “wavelength in the ultraviolet range” refers to a wavelength of at least 1 nm and less than 400 nm. Various solid lasers such as an excimer laser and YAG laser can be employed for the first laser beam. In particular, an excimer laser having the wavelength of 308 nm is preferable.

In the case where the at least two types of laser beams include the first laser beam and the second laser beam set forth above, the process of recrystallization of molten silicon must be controllable through the second laser beam. In other words, it is required that the second laser beam can heat the precursor semiconductor thin film substrate having an amorphous semiconductor region, and be absorbable by molten silicon. Therefore, a laser beam having a wavelength in the visible range or infrared range (a laser beam having a wavelength from the visible range to infrared range) is preferable. As used herein, “wavelength in the visible range” refers to a wavelength of at least 400 nm and less than 750 nm. “Wavelength in the infrared range” refers to a wavelength of at least 750 nm and not more than 1 mm. Particularly suitable for such a second laser beam is the beam of, for example, a YAG laser having the wavelength of 532 nm, a YAG laser having the wavelength of 1064 nm, or a CO₂ laser having the wavelength of 10.6 μm.

The absorptance of liquid silicon with respect to light of 532 nm and 1064 nm in wavelength is approximately 60% (refer to Japanese Patent Laying-Open No. 05-235169). The absorptance of liquid silicon with respect to light of 10.6 μm in wavelength is approximately 10-20% (results of experiments carried out by inventors of present invention). Therefore, a laser of 532 nm and 1064 nm in wavelength having high absorptance with respect to molten silicon is to be employed in the third method.

In the present invention, the first to third methods set forth above can be used singularly, or in combination by at least two of the three methods. Which method to be used can be determined appropriately depending upon the crystal growth condition.

Semiconductor Thin Film Fabrication Apparatus

A semiconductor thin film fabrication apparatus of the present invention includes at least two laser light sources that can irradiate a precursor semiconductor thin film substrate with at least two types of laser beams, a sensing unit that can sense change in reflectance of a site of a precursor semiconductor thin film substrate irradiated with a predetermined reference laser beam, and a control unit that can control the radiation timing or power density of the at least two types of laser beams according to change in reflectance of a site of the precursor semiconductor thin film substrate irradiated with the reference laser beam.

In the semiconductor thin film fabrication apparatus of the present invention, “at least two types of laser beams” include a first laser beam having a wavelength that can be absorbed by the precursor semiconductor thin film and energy that can melt the precursor semiconductor thin film, and a second laser beam having a wavelength and energy that can control the process of recrystallization of the molten precursor semiconductor thin film.

In the present invention, “reference laser beam” is a laser beam determined arbitrarily in advance from the at least two types of laser beams. The reference laser beam is emitted to a precursor semiconductor thin film prior to emission of a laser beam directed to melting-recrystallization of the precursor semiconductor thin film. When the first laser beam and the second laser beam set forth above are employed, the second laser beam may be used as the reference laser be am. Alternatively, another laser beam (third laser beam) may be applied as the reference laser beam.

In the present invention, “change in reflectance” refers to change in the ratio of the power density of the reference laser beam emitted after reflection at the precursor semiconductor thin film with respect to the power density of the reference laser beam before reflection. The semiconductor thin film fabrication apparatus of the present invention will be described in detail hereinafter with reference to drawings.

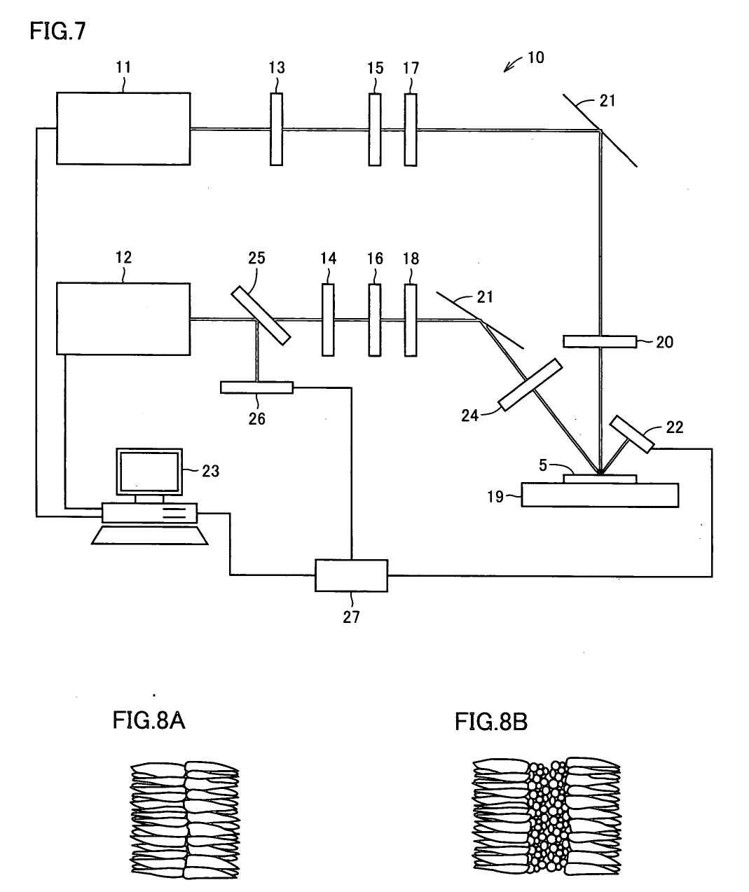

FIG. 7 schematically shows a preferable example of a semiconductor thin film fabrication apparatus 10 of the present invention. Referring to FIG. 7, semiconductor thin film fabrication apparatus 10 includes, as the at least two laser light sources, a first laser light source 11 emitting a first laser beam having a wavelength that can be absorbed by a precursor semiconductor thin film and energy that can melt the precursor semiconductor thin film, and a second laser light source 12 emitting a second laser beam having a wavelength and energy that can control the process of recrystallization of the molten precursor semiconductor thin film.

Semiconductor thin film apparatus 10 further includes sensors 22 and 26, and a signal processing circuit 27 constituting the sensing means that can sense change in reflectance of a site irradiated with the second laser beam identified as the reference laser beam. Signal processing circuit 27 processes a signal indicating the power density of the second laser beam before reflection, and a signal indicating the power density of the second laser beam after reflection, transmitted from sensors 22 and 26, respectively, to generate a signal indicating the reflectance.

Semiconductor thin film apparatus 10 further includes a control unit 23 connected to first and second laser light sources 11 and 12 to control the radiation timing or power density of the first or second laser beam according to change in reflectance of a site of the precursor semiconductor thin film irradiated with the second laser beam. Control unit 23 is connected to signal processing circuit 27 to receive the signal of reflectance generated by signal processing circuit 27.

Semiconductor thin film fabrication apparatus 10 of FIG. 7 can be suitably implemented by appropriate combination of a laser oscillator, various types of optical components, sensing means, and control means well known and used conventionally in the field of art.

Semiconductor thin film fabrication apparatus 10 of FIG. 7 is configured such that the first laser beam emitted from first laser oscillator 11 passes through an attenuator 13, a uniform radiation optical system 15, a mask 17, and an imaging lens 20, constituting the first laser light path, to be impinged on a substrate composite 5. Substrate composite 5 is mounted on a stage 19 that can move horizontally at a predetermined speed.

First laser oscillator 11 is not particularly limited, as long as it is capable of emitting a laser beam having a wavelength that can be absorbed by a precursor semiconductor thin film and that can melt the precursor semiconductor thin film. From the standpoint of applying great energy to a thin film in an extremely short period of time on the order of ns (nano second) to μs (micro second), and favorable absorption of light in the ultraviolet range by the silicon thin film, first laser oscillator 11 is preferably a light source that can emit a laser beam having a wavelength in the ultraviolet range.

For example, solid lasers such as an excimer laser and YAG laser can be employed as the first laser oscillator. Particularly, a laser oscillator that can emit an excimer laser beam of 308 nm in wavelength is suitable. Also, the first laser oscillator preferably emits a pulsive energy beam.

The laser beam emitted from first laser oscillator 11 is attenuated to a predetermined luminous energy by attenuator 13 located in the first laser light path to have the power density adjusted. Then, the first laser beam has the power density distribution rendered uniform by uniform radiation optical system 15 to be shaped to an appropriate dimension, and applied evenly on the pattern formation face of mask 17. The image of mask 17 is formed on substrate composite 5 by imaging lens 20 at a predetermined magnification (for example, ¼). Mirror 21 provided at the first light path to reflect the laser beam is not limited in location and number, and can be arranged appropriately according to the design of the optical system and configuration of the apparatus.

In semiconductor thin film fabrication apparatus 10 of FIG. 7, the second laser beam emitted from second laser oscillator 12 passes through an attenuator 14, a uniform radiation optical system 16, a mask 18, and an imaging lens 24, constituting a second laser light path, to be applied on substrate composite 5. The location of beam splitter 25 is not limited to the position between second laser oscillator 12 and attenuator 14, and may be located anywhere between second laser oscillator 12 and substrate composite 5.

Second laser oscillator 12 is not particularly limited, as long as it is capable of emitting a laser beam having a wavelength and energy that can control the process of recrystallization of molten precursor semiconductor thin film. From the standpoint of controlling the process of recrystallization of molten silicon and heating the precursor semiconductor thin film, as well as favorable absorption by molten silicon, second laser oscillator 12 is preferably a light source that can emit a laser beam having a wavelength in the visible range or infrared range (a laser beam having a wavelength from the visible range to infrared range).

For example, a YAG laser having the wavelength of 532 nm, a YAG laser having the wavelength of 1064 nm, or a CO₂ laser having the wavelength of 10.6 μm is preferable. Further, the second laser oscillator may output a laser beam continuously, or in a pulsive manner.

The laser beam emitted from second laser oscillator 12 is attenuated to a predetermined luminous energy by attenuator 14 located in the second laser light path to have the power density adjusted. Then, the second laser beam has the power density distribution rendered uniform by uniform radiation optical system 16 to be shaped to an appropriate dimension, and applied evenly on the pattern formation face of a mask 18. The image of mask 18 is formed on substrate composite 5 by imaging lens 24 at a predetermined magnification. Mirror 21 provided at the second light path to reflect the laser beam is not limited in location and number, and can be arranged appropriately according to the design of the optical system and configuration of the apparatus. Beam splitter 25 is used to diverge the second laser beam at a predetermined ratio and deliver a portion of the second laser beam to sensor 22.

The sensing unit is formed of sensor 22, sensor 26, and signal processing circuit 27. Each of sensors 22 and 26 is configured to measure the power density of the second laser beam on the precursor semiconductor thin film before reflection and after reflection. Such sensors 22 and 26 are not particularly limited, as long as they are capable of measuring the aforementioned power density. Well-known sensing means conventionally used such as an optical sensor, a pyroelectric sensor, and the like may be employed. Particularly, an optical sensor that is superior in high response is preferable.

The optical sensor, when employed, is not particularly limited, and an optical sensor having the photosensitive unit formed of Si may be used. When a YAG laser of 1064 nm in wavelength is employed as the second light source, the photosensitive unit is preferably formed of AgOCs or InGaAs. When a CO₂ laser of 10.6 μm in wavelength is employed as the second light source, the photosensitive unit is preferably formed of HdCdZnTe. Further, the optical sensor preferably includes an attenuator optical system (not shown) by virtue of possessing predetermined laser resistance.

Signal processing circuit 27 is preferably implemented to generate a signal representing the ratio of the power density after reflection to the power density before reflection, based on a signal 41 from sensor 26 indicating the power density of the second laser beam before reflection and a signal 42 from sensor 22 indicating the power density of the second laser beam after reflection, and output the generated signal to control unit 23.

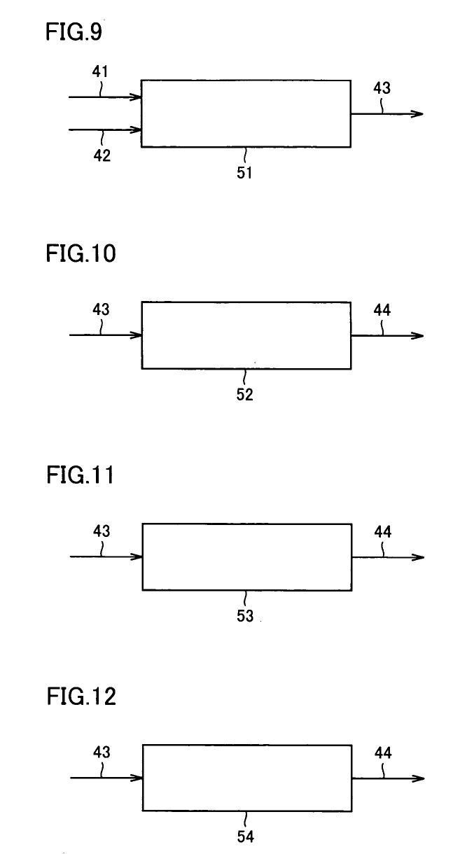

Referring to FIG. 9, signal processing circuit 27 is formed of circuitry 51 including a division circuit 51 to process signals 41 and 42 through circuitry 51 to generate and provide to control unit 23 a signal 43 representing the ratio of the power density after reflection with respect to the power density before reflection, i.e. a voltage value indicating reflectance.

Control unit 23 is not particularly limited, as long as it can control the radiation timing or power density of the first or second laser beam according to a voltage value representing the reflectance of the second laser beam at the semiconductor thin film substrate, output from signal processing circuit 27. Control unit 23 takes a different configuration depending upon which of the first to third methods corresponding to a preferable semiconductor thin film fabrication method of the present invention is applied.

For example, the control unit in the semiconductor thin film fabrication apparatus employed in accordance with the first method is implemented to control the radiation timing of the first laser beam according to change in reflectance obtained from the power density of the second laser beam after reflection with respect to the power density of the second laser beam before reflection, sensed by the sensing unit.

Specifically, control unit 23 includes a circuit formed mainly of a comparator. Referring to FIG. 10, detection is made that signal 43 representing the ratio of the power density of the second laser beam after reflection from the semiconductor thin film substrate with respect to the power density of the second laser beam before reflection, output from signal processing circuit 27, reaches a predetermined voltage value at control unit 23 including a circuit 52 formed mainly of a comparator, whereby a signal 44 for emission of the first laser beam can be generated. “Predetermined voltage value, output from signal processing circuit 27” corresponds to the reflectance, and can be set to a desired value.

The control unit in a semiconductor thin film fabrication apparatus in accordance with the second method is implemented to control the power density of the first laser beam according to change in reflectance obtained from the power density after reflection of the second laser beam with respect to the power density before reflection of the second laser beam, sensed by the sensing unit.

Specifically, control unit 23 is formed of circuitry 53 mainly including a sample/hold circuit, a circuit that can generate a sample pulse, and an inverting amplifier circuit to modify the voltage value output to the first laser oscillator by a predetermined voltage value, according to the voltage value of signal 43, output from signal processing circuit 27, as shown in FIG. 11, representing the ratio of the power density of the second laser beam before reflection with respect to the power density of the second laser beam before reflection at the semiconductor thin film substrate. In other words, a signal 44 for emission of the first laser beam can be transmitted. More specifically, when the signal from signal processing circuit 27 attains at least a predetermined voltage value at a predetermined time (for example, the point in time of initiating emission of the first laser beam), signal 44 that is to be output to the first laser oscillator is set smaller than the predetermined voltage value. When the signal output from signal processing circuit 27 is smaller than the predetermined voltage value, signal 44 that is to be output to the first laser oscillator is set larger than the predetermined voltage value. “Predetermined voltage value output to the first laser oscillator” serves to determine the power density of the first laser beam, and can be set at a desired value.

The control unit in the semiconductor thin film fabrication apparatus in accordance with the third method is implemented to control the power density of the second laser beam according to change in reflectance obtained from the power density after reflection of the second laser beam with respect to the power density before reflection of the second laser beam, sensed by the sensing unit.

Specifically, control unit 23 is formed of circuitry 54 mainly including a sample/hold circuit, a circuit that can generate a sample pulse, and an inverting amplifier circuit to modify the voltage value output to the second laser oscillator by a predetermined voltage value, according to the voltage value of signal 43 representing the ratio of the power density of the second laser beam after reflection at the semiconductor thin film substrate with respect to the power density of the second laser beam before reflection, output from signal processing circuit 27, as shown in FIG. 12.

More specifically, when the signal output from signal processing circuit 27 is equal to or greater than the predetermined voltage value at a predetermined time (for example, the point in time of initiating emission of the first laser beam), signal 44 output to the second laser oscillator is set smaller than the predetermined voltage value. When the signal output from signal processing circuit 27 is smaller than the predetermined voltage value, the signal to the second laser oscillator is set larger than the predetermined voltage value. “Predetermined voltage value output to the second laser oscillator” serves to determine the power density of the second laser beam, and can be set to a desired value.

The control unit set forth above can be realized by using appropriate control means well known in conventional art, or by a combination thereof, according to the control condition. Although not depicted, control unit 23 preferably is implemented to conduct control of the position of stage 19, store the laser radiation target position, control the temperature in the apparatus, and control the atmosphere in the apparatus.

Although the above embodiment was described in which the sensing unit is formed of an optical sensor and signal processing circuit that senses change in the power density of the second laser beam after reflection with respect to the power density of the second laser beam before reflection, the sensing unit in the semiconductor thin film fabrication apparatus of the present invention may be any sensing unit that can sense change in reflectance of a site on the precursor semiconductor thin film irradiated with the reference laser beam. For example, a laser light source (a third laser light source) that can emit a third laser beam can be provided. Using this third laser beam as the reference laser beam, an optical sensor can be employed capable of sensing corresponding to the wavelength of the third laser beam. In this case, a laser beam having a wavelength that exhibits greater change in reflectance with respect to change in temperature of the precursor semiconductor thin film is preferably used as the third laser beam. For example, comparison was conducted through experiments between a YAG laser having a wavelength of 532 nm and a carbon dioxide gas laser having a wavelength of 10.6 μm employed as the reference laser beam. The inventors of the present invention identified that, when the temperature of the precursor semiconductor thin film substrate is in the vicinity of 300° C., the change in reflectance for every 10° C. change in temperature at the precursor semiconductor thin film substrate was 0.07% and 0.09%, respectively. Since temperature difference can be sensed more easily if the change in reflectance per unit temperature is greater, the carbon dioxide gas laser is more preferable. In this case, an optical sensor having the photosensitive unit formed of HdCdZnTe is preferably used.

By using the semiconductor thin film fabrication apparatus of the present invention, the semiconductor thin film fabrication method of the present invention set forth above can be carried out in a suitable manner. A semiconductor thin film including a polycrystalline semiconductor region having the length of crystal increased significantly in the lateral growth distance can be fabricated in stability, without difference in the length of crystal formed caused by energy variation for each radiation. As a result, a thin film transistor having the performance improved significantly, as compared to a conventional one, can be fabricated in stability.

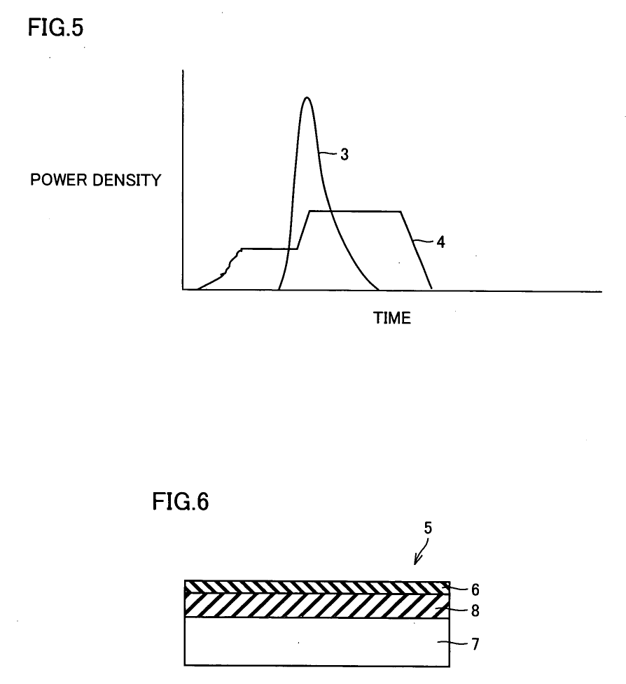

In the present invention, substrate composite 5 is formed of a precursor semiconductor thin film on an insulative substrate. As used herein, a precursor semiconductor thin film refers to a semiconductor thin film under a state prior to being melted and recrystalized by the fabrication method and fabrication apparatus of a semiconductor thin film of the present invention, i.e. a semiconductor thin film that is not yet processed. FIG. 6 schematically shows a preferable example of substrate composite 5 that can be employed in the present invention. Referring to FIG. 6, substrate composite 5 has a precursor semiconductor layer 6 formed on an insulative substrate 7 with a buffer layer 8 therebetween. In substrate composite 5, precursor semiconductor thin film 6 is formed on insulative substrate 7 by CVD (Chemical Vapor Deposition), for example.

A substrate well known in the field of art formed of a material including glass, quartz, or the like can be suitably employed as insulative substrate 7. It is desirable to use a glass insulative substrate from the standpoint of economic perspective and ease in fabricating a large-area insulative substrate. The thickness of the insulative substrate is preferably, but not limited to, 0.5-1.2 mm. This is because, if the thickness of the insulative substrate is less than 0.5 mm, the insulative substrate may easily crack. Furthermore, it may become difficult to fabricate a substrate of high planarity. If the thickness of the insulative substrate exceeds 1.2 mm, the substrate may become too thick or too heavy when a display device is provided.

In substrate composite 5, recursor semiconductor thin film 6 is preferably formed on insulative substrate 7 with buffer layer 8 therebetween, as shown in FIG. 6. The provision of buffer layer 8 suppresses the heat effect of molten precursor semiconductor thin film 6 on the insulative substrate that is a glass substrate during melting-recrystallization using a laser beam. Furthermore, impurity diffusion into precursor semiconductor thin film 6 from insulative substrate 7 can be prevented. Buffer layer 8 is not particularly limited, and can be formed by, for example CVD or the like, using a material conventionally employed in the field of art such as silicon oxide, silicon nitride, and the like. Particularly, it is preferable to form buffer layer 8 based on silicon oxide since the component is similar to that of the glass substrate, and various physical properties are substantially equal. The thickness of buffer layer 8 is preferably, but not limited to, 100-500 nm. This is because, if the buffer layer is too thin, the effect of preventing impurity diffusion may be insufficient. Furthermore, if the buffer layer is too thick, the time required for growing the film may become too time-consuming.

Precursor semiconductor thin film 6 in substrate composite 5 is not particularly limited, and an arbitrary semiconductor material can be employed as long as it is an amorphous semiconductor or crystalline semiconductor. As a specific example of the material of precursor semiconductor thin film 6, a material including amorphous silicon such as hydrated amorphous silicon (a-Si: H) is preferable due to the fact that it is conventionally used in the fabrication of a liquid crystal display element and that fabrication is feasible. Such materials include, but not limited to, material containing amorphous silicon. A material containing polycrystalline silicon inferior in polycrystallinity, or a material containing microcrystal silicon may be used. Furthermore, the material of the precursor semiconductor thin film is not limited to a material formed only of silicon. A material with silicon as the main component and including other elements such as germanium may be employed. For example, addition of germanium allows arbitrary control of the forbidden band width of the precursor semiconductor thin film.

The thickness of precursor semiconductor thin film 6 is preferably, but not limited to, 30-200 nm. This is because, if the precursor semiconductor thin film is too thin, it may be difficult to grow a film with uniform thickness. Furthermore, if the precursor semiconductor thin film is too thick, the time required for growing the film may be increased.

The present invention will be described in further detail based on examples set forth below. It is to be understood that the present invention is not limited to these examples.

### EXAMPLE 1

Using a semiconductor thin film fabrication apparatus configured as shown in FIG. 7, a semiconductor thin film was fabricated in accordance with a semiconductor thin film fabrication method of the present invention. Specifically, a second laser beam shaped into a rectangle such that the size on the substrate plane is 5.5 mm×5.5 mm was directed obliquely onto a substrate composite, as the reference laser beam. The first laser beam shaped into a rectangle such that the size on the substrate plane is 40 μm×500 μm in accordance with change of the power density of reflected light of the second laser beam was directed perpendicularly.

An excimer laser having a wavelength of 308 nm emitting pulsive energy was employed for the first laser beam. A carbon dioxide gas laser having a wavelength of 10.6 μm emitting pulsive energy was employed for the second laser beam. The energy fluence of the first laser beam was set to 3000 J/m². The energy fluence of the second laser beam was set to 8100 J/m². The pulse width (radiation time) was set to 130 μsec.

The power density of the second laser beam before reflection and after reflection was sensed using an optical sensor (PD-10.6 Series Photovoltaic CO₂ Laser Detector from Vigo System; photosensitive unit formation material: HdCdZnTe; rise time: not more than approximately 1 nsec) and a signal processing circuit, based on change in the voltage value representing the power density after reflection with respect to the voltage value representing the power density before reflection. The sensed result by the sensing unit formed of the optical sensor and signal processing circuit was output as a voltage value to the control unit. The radiation timing of the first laser beam was controlled through the control unit based on the output of the sensed result from the optical sensor.

### EXAMPLE 2

A semiconductor thin film was fabricated using a semiconductor thin film fabrication apparatus similar to that of Example 1, provided that the control unit was implemented to modify the setting of the radiation energy of the first laser beam according to the sensed result of the optical sensor set forth above immediately before emission of the first laser beam.

As shown in FIG. 1, the substrate composite was irradiated with the second laser beam identified as the reference laser beam, and then irradiated with the first laser beam at an elapse of a predetermined period of time (120 μsec from the radiation initiation time of the second laser beam when the power density of the second laser beam was set to 62.3 MW/m²).

In this context, the radiation energy of the first laser beam was set according to the detected result of optical sensor 22 immediately before emission of the first laser beam to control the power density. For example, when the power density before reflection that is calculated based on the power density of reflected light is lower than 62.3 MW/m² in the case where the pulse width of the second laser beam is set to 130 μsec, the energy fluence of the first laser beam was set higher than 3000 J/m².

### EXAMPLE 3

A semiconductor thin film was fabricated employing a semiconductor thin film fabrication apparatus similar to that of Example 1, provided that the optical sensor was implemented to sense change in the power density of reflected light immediately before emission of the first laser beam and that silicon has melted by the irradiation with the first laser beam. Further, the control unit was implemented to control the power density of the second laser beam in accordance with the sensed result from the optical sensor immediately before emission of the first laser beam.

The substrate composite was irradiated with the second laser beam identified as the reference laser beam, and then irradiated with the first laser beam at an elapse of a predetermined period of time (120 μsec after initiating radiation of the second laser beam, when the power density of the second laser beam was set to 62.3 MW/m²), as shown in FIG. 5. In this context, the power density of the second laser beam was modulated after the precursor semiconductor thin film is melted by the first laser beam.

### COMPARATIVE EXAMPLE 1

For comparison; a semiconductor thin film was fabricated using a conventional semiconductor thin film fabrication apparatus similar to that employed in Example 1, provided that the sensing unit and control unit are absent.

The substrate composite was irradiated with the second laser beam, and then irradiated with the first laser beam at an elapse of the predetermined period of time (120 μsec from initiating radiation of the second laser beam). The energy fluence of the first laser beam was set to 3000 J/m²; the energy fluence of the second laser beam was set to 8100 J/m²; and the pulse width (radiation time) was set to 130 μsec.

TABLE 1

| | Distance of Lateral Growth (μm) |
|---|---|
| Example 1 | 17-18 |
| Example 2 | 17-18 |
| Example 3 | 17-18 |
| Comparative Example 1 | 12-18 |

The above Table 1 indicates the distance of lateral growth in semiconductor thin films produced by Examples 1-3 and Comparative Example 1 set forth above. It is appreciated from Table 1 that a crystal having the length increased significantly can be obtained in stability in accordance with the fabrication method of the present invention.

Conventionally, difference in the length of crystal for each radiation imposes the problem that, when a semiconductor device with the crystallized portion identified as the active layer is fabricated, the characteristics thereof, particularly the mobility, differ for each radiation. This is because the grain boundary is present with respect to the moving direction of electrons in the channel region when the length of the crystal formed is shorter than the desired length of crystal. When the length of crystal formed becomes smaller than the feed pitch, the crystal formed by the one preceding radiation cannot be succeeded. Therefore, the feed pitch is determined based on the shortest length of crystal formed in super lateral growth. Thus, the feed pitch had to be determined based on the shortest length of crystal that was 12 μm in the comparative example shown in Table 1. In contrast, the feed pitch can be determined based on 17 μm, that is the shortest length of crystal, according to the method of the present invention. This means that a longer pitch can be set in the present invention as compared to the conventional example, allowing a longer crystal to be obtained with fewer number of radiations.

The present invention may be applied, not only to lateral growth in which needle like crystals are grown laterally, but also to crystallization in which crystals are grown in the conventional vertical direction. In this case, crystals of large grain size can be formed in stability.

Although the present invention has been described and illustrated in detail, it is clearly understood that the same is by way of illustration and example only and is not to be taken by way of limitation, the spirit and scope of the present invention being limited only by the terms of the appended claims.

1. A fabrication method of a semiconductor thin film including a polycrystalline semiconductor region by irradiating a precursor semiconductor thin film substrate with at least two types of laser beams, and melting-recrystallizing the precursor semiconductor thin film,
wherein a radiation timing or power density of said at least two types of laser beams is controlled according to change in reflectance of a site of said precursor semiconductor thin film substrate irradiated with a predetermined reference laser beam.

2. The fabrication method of a semiconductor thin film according to claim 1, wherein said at least two types of laser beams comprise a first laser beam having a wavelength that can be absorbed by said precursor semiconductor thin film and energy that can melt said precursor semiconductor thin film, and a second laser beam having a wavelength and energy that can control a process of recrystallization of the molten precursor semiconductor thin film.

3. The fabrication method of a semiconductor thin film according to claim 2, wherein said reference laser beam is a second laser beam, and radiation timing or power density of the first or second laser beam is controlled according to change in reflectance of said second laser beam to melting-recrystallize said precursor semiconductor thin film.

4. The fabrication method of a semiconductor thin film according to claim 3, wherein the first laser beam is emitted according to change in reflectance obtained from the power density after reflection of the second laser beam emitted with respect to the power density before reflection of the second laser beam at said precursor semiconductor thin film substrate.

5. The fabrication method of a semiconductor thin film according to claim 4, wherein said first laser beam is emitted after said reflectance reaches a predetermined value.

6. The fabrication method of a semiconductor thin film according to claim 5, wherein said predetermined value of reflectance is determined by a desired length of crystal and the power density of the first laser film.

7. The fabrication method of a semiconductor thin film according to claim 3, wherein the power density of the first laser beam is controlled according to change in reflectance obtained from the power density after reflection of the second laser beam emitted with respect to the power density before reflection of the second laser beam at said precursor semiconductor thin film substrate.

8. The fabrication method of a semiconductor thin film according to claim 7, wherein said power density of the first laser beam is determined from a relationship between the reflectance immediately before emission of the first laser beam and a desired length of crystal.

9. The fabrication method of a semiconductor thin film according to claim 3, wherein the power density of the second laser beam is controlled according to change in reflectance obtained from the power density after reflection of the second laser beam emitted with respect to the power density before reflection of the second laser beam at said precursor semiconductor thin film substrate.

10. The fabrication method of a semiconductor thin film according to claim 9, wherein said power density of the second laser beam is determined from a relationship between a desired length of crystal and a value of reflectance immediately before emission of the first laser beam.

11. The fabrication method of a semiconductor thin film according to claim 2, wherein said first laser beam has a wavelength in an ultraviolet range or visible range, and said second laser beam has a wavelength in a visible range or infrared range.

12. The fabrication method of a semiconductor thin film according to claim 2, wherein said second laser beam has a wavelength in a range of 9-11 μm.

13. The fabrication method of a semiconductor thin film according to claim 1, wherein a crystal grown during recrystallization is grown substantially parallel to a plane of the semiconductor thin film substrate.

14. A semiconductor thin film fabrication apparatus comprising:
at least two laser light sources that can irradiate a precursor semiconductor thin film substrate with at least two types of laser beams,
a sensing unit that can sense change in reflectance of a site of the precursor semiconductor thin film substrate irradiated with a predetermined reference laser beam, and
a control unit controlling a radiation timing or power density of said at least two types of laser beams according to change in reflectance of a site of said precursor semiconductor thin film substrate irradiated with said reference laser beam.

15. The semiconductor thin film fabrication apparatus according to claim 14, wherein
said at least two laser light sources comprise a first laser light source emitting a first laser beam having a wavelength that can be absorbed by the precursor semiconductor thin film and energy that can melt the precursor semiconductor thin film, and a second laser light source emitting a second laser beam having a wavelength and energy that can control a process of recrystallization of the molten precursor semiconductor thin film,
said sensing unit can sense change in reflectance of a site irradiated with the second laser beam, when said reference laser beam is the second laser beam, and
said control unit can control radiation timing or power density of the first laser beam or second laser beam according to change in reflectance of a site of said precursor semiconductor thin film substrate irradiated with the second laser beam.

16. The semiconductor thin film fabrication apparatus according to claim 15, wherein said sensing unit can sense change in reflectance obtained from the power density after reflection of the second laser beam emitted with respect to the power density before reflection of the second laser beam at said precursor semiconductor thin film substrate.

17. The semiconductor thin film fabrication apparatus according to claim 16, wherein
said sensing unit includes an optical sensor, and a signal processing circuit processing a signal from said optical sensor,
said optical sensor is arranged so as to sense said second laser beam before reflection and said second laser beam after reflection at said precursor semiconductor thin film substrate, and
said signal processing circuit processes a signal indicating the power density of the second laser beam before reflection and a signal indicating the power density of the second laser beam after reflection, transmitted from said optical sensor, to generate a signal indicating reflectance.

18. The semiconductor thin film fabrication apparatus according to claim 15, wherein said first laser light source emits a first laser beam having a wavelength in an ultraviolet range, and said second laser light source emits a second laser beam having a wavelength in a visible range or infrared range.

19. The semiconductor thin film fabrication apparatus according to claim 15, wherein the second laser beam emitted from said second laser light source has a wavelength in a range of 9-11 μm.

20. The semiconductor thin film fabrication apparatus according to claim 14, wherein a crystal grown during recrystallization is grown substantially parallel to a plane of the semiconductor thin film substrate.
